(19) United States
(12) Patent Application Publication
(10) Pub. No.: US 2019/0267574 A1
(43) Pub. Date: Aug. 29, 2019

(54) LIGHT SCATTERING FILM WITH ENHANCED EXTRACTION PERFORMANCE

(71) Applicant: SABIC GLOBAL TECHNOLOGIES B.V., Bergen op Zoom (NL)

(72) Inventors: Duygu Deniz GUNBAS, Bergen op Zoom (NL); Dirk VELDMAN, Eindhoven (NL)

(73) Assignee: SABIC GLOBAL TECHNOLOGIES B.V., Bergen op Zoom (NL)

(21) Appl. No.: 16/343,502

(22) PCT Filed: Oct. 20, 2017
(86) PCT No.: PCT/IB2017/056542

§ 371 Date: Apr. 19, 2019

Related U.S. Application Data
(60) Provisional application No. 62/411,177, filed on Oct. 21, 2016.

(51) Int. Cl. H01L 51/52; H01L 51/56; G02B 5/02; H01L 51/00

(52) U.S. Cl. CPC H01L 51/5268; H01L 51/56; G02B 5/0242; G02B 5/0278; H01L 51/5056; H01L 51/0034; H01L 2251/5369; H01L 2251/308; H01L 51/0081

(57) ABSTRACT

A composition may include a polymer matrix and a light scattering component disposed in the polymer matrix. The light scattering component includes nanoparticles of a polydisperse particle size distribution. Each of at least 60% of the nanoparticles has a particle size of less than 100 nm and each of 80-100% of the nanoparticles has a particle size of less than 200 nm.

### TECHNICAL FIELD

The present disclosure relates to light emitting devices, and more particularly to organic light emitting devices and light scattering films for enhancing light extraction.

### BACKGROUND

Today, organic light emitting devices/diodes (OLEDs) are increasingly used in lighting applications because they may be more energy efficient than other conventional lighting sources and may be applied in thin and flexible form factors more readily than other conventional lighting sources. OLEDs typically have a stacked structure composed of one or more organic layers positioned between two electrodes, e.g. a cathode and an anode. The organic layers in an OLED are often composed of electroluminescent polymers that emit light when a voltage is applied across the anode and the cathode. At least one of the two electrodes, either the anode or the cathode electrode, is formed from a transparent conductive material, which enables the light emitted from the OLED to be visible.

Light extraction efficiency may refer to the ability of a light emitting diode (LED) device to provide light from the light emitting portion of the LED to the surrounds such that the light may be useful. Generally, the extraction efficiency of OLEDs is quite low because of differences in the refractive indices between air, the substrate, and the organic/electrode layers. Improving extraction efficiency is critical because higher extraction will yield additional energy savings, prolong the lifetime of the device and increase cost savings. Improving extraction efficiency, however, remains a significant challenge for lighting applications using OLEDs.

In a conventional OLED device, only about 20% of the light generated is emitted to the environment. The remaining light is generally confined in the device (e.g., internally reflected or trapped in the substrate, guided in the organic layers and the transparent electrode, or bound as surface plasmon polaritons at the metallic contact). One cause of light extraction problems for the substrate and the guided modes is the total internal reflection (TIR) at the interfaces due to refractive index mismatch between the layers. TIR may occur between a transparent electrode (refractive index ˜1.8) and the substrate (refractive index ˜1.5); and between the substrate (refractive index ˜1.5) and air (refractive index ˜1.0). In view of above, there remains a need for improving the outcoupling efficiency, i.e., light extraction efficiency, of OLED devices, while being cost effective and compatible with existing OLED manufacturing processes to be commercially successful.

Different technical methods and approaches have been suggested to address the issue of inefficient light extraction. Examples include surface roughening, surface texturing, and the use of microlens arrays. However, such external light extraction can only address the light loss at the substrate—air interface, and not the light loss at other interfaces, most particularly at the transparent electrode—substrate interface.

Alternatively, high refractive index substrates can be used, but these are expensive and raise concerns about environmental impact and toxicity. Korean Patent Application 10-2010-013839, the disclosure of which is incorporated herein by this reference in its entirety, discloses a silicon oxide based scattering glass substrate obtained by forming pores in a high refractive index glass. Nevertheless, such a scattering glass plate is not suitable for employment in various shapes and forms in view of its process and cannot be directly applied on a light emitting device.

Another way to overcome the light extraction efficiency limitation is to use an internal light extraction layer between the substrate and the transparent electrode layer of an OLED. Scattering particles present in the layer allow the light to be extracted to be scattered, providing an additional chance for the light to escape. Published European Application EP2674442A2, the disclosure of which is incorporated herein by this reference in its entirety, describes a light scattering layer including scattering particles within a binder including metallic oxide particles. Scattering particles have an average particle diameter of 200 nanometers (nm) to 500 nm, and have a content of 20 volume percent (vol %) or less of particles with a diameter of 600 nm or more with respect to the total amount of scattering particles. Furthermore, the scattering particles typically have a coefficient of variation (CoV=std particle diameter/average particle diameter) of 30% or less. However, large particle size of the scatterers leads to current leakage and defective devices due to poor surface quality of the layer. Application of a high index smoothing layer generally decreases the surface roughness but increases the processing complexity. Additionally, larger scattering particles give rise to smaller scattering angle even when the scattering intensity is high. This leads to a decrease in extraction efficiency and variation in color tone due to a large variation of the light extraction efficiency depending on wavelength.

In addition, it has been disclosed in US. Patent Publ. no. 2016/0049610 A1, the disclosure of which is incorporated herein by this reference in its entirety, that a nanocomposite composition exhibiting bimodal (or plurimodal) particle size distribution provides advantageous optical properties for electronic devices such as organic light emitting diodes (OLEDs). The nanocomposite includes 10-80 wt % of the agglomerates having a particle size of less than 30 nm and less than 20 wt % of the agglomerates having a particle size of at least 100 nm, preferably at least 400 nm, based on the total weight of the agglomerates. In order to obtain optimal scattering, nanoparticles present as larger clusters are necessary. The inventors claim to have the best scattering properties with clusters having a diameter of about 600 nm. Nevertheless, the main problem of such compositions is the insufficient scattering effect due to a large ratio of small vs large agglomerates. As a result, significantly high loading of light scatterers are needed to achieve sufficient light extraction efficiency.

Furthermore, as described in EP2674442A2, the disclosure of which is incorporated herein by this reference in its entirety, it is expected that a large particle size of bigger agglomerates, especially agglomerates with a diameter of 600 nm, would potentially induce electrical defects resulting from surface unevenness. When the unevenness of the internal extraction layer is large, film thickness unevenness occurs or fine protrusions are formed in the transparent electrode deposited on the light extraction layer. This leads to the generation of local large current flows causing a short circuit or shortening of device lifetime.

Therefore, current approaches towards OLEDs with efficient light extraction are often limited to single color emission, are cost inefficient, are limited and/or are insufficient in light extraction efficiency.

These and other shortcomings are addressed by aspects of the present disclosure

### SUMMARY

In accordance with one aspect of the disclosure, a composition may include a polymer matrix and a light scattering component disposed in the polymer matrix. The light scattering component includes nanoparticles of polydisperse particle size distribution. At least 60% of the nanoparticles have a particle size of less than 100 nm and each of 80-100% of the nanoparticles have a particle size of less than 200 nm.

In another aspect, a composition may include a polymer matrix and a first portion of light scattering particles dispersed in the polymer matrix. An average particle size of the first portion of light scattering particles is less than 100 nm and a second portion of light scattering particles are dispersed in the polymer matrix. An average particle size of the second portion of light scattering particles is less than 200 nm. The first portion of light scattering nanoparticles includes at least 60% of the total number of light scattering particles and the second portion of light scattering particles includes 20-40% of the total number of light scattering particles, excluding the first portion.

### BRIEF DESCRIPTION OF THE DRAWINGS

The above-mentioned and other features and advantages of this disclosure, and the manner of attaining them, will become apparent and be better understood by reference to the following description of one aspect of the disclosure in conjunction with the accompanying drawings, wherein:

FIG. 1 is a schematic illustration of an OLED, according to an aspect of the disclosure.

FIG. 2 a schematic illustration of an OLED, according to an aspect of the disclosure.

FIG. 3 is a plot of CIE x (left axis) and y (right axis) coordinates of a white OLED with Ex.1 and C.Ex.2 as scattering layer, according to aspects of the disclosure.

### DETAILED DESCRIPTION

The present disclosure relates to a light scattering layer, which may be disposed between a substrate and a transparent electrode layer of an OLED device. The light scattering layer may include a particular distribution of scattering particles in a polymer matrix. A selective particle size and refractive index combination may be configured to provide desired optical characteristics, such as enhanced extraction, for the resulting system.

The introduction of the light scattering layer as an internal light extraction layer (IEL) in an OLED stack may enhance the efficiency of these stacks by more than 100% relative to the reference device without the IEL layer. Alternatively or additionally, for white OLEDs, a substantial improvement of the color stability with respect to viewing angle may be achieved using the IEL of the present disclosure.

The particle size and distribution of the scattering particles (e.g., nanoparticles, nanocrystals, etc.) in a polymer matrix may be calculated using SETFOS (Semiconductor Thin Optics Simulation) software. As an example, the scattering particles in a given sample show a polydisperse particle size distribution with 63% of the particles having a particle size of less than 100 nm and 37% of the particles having a particle size of less than 200 nm with respect to the total amount of scattering particles. The scattering effect of the particles was calculated according to Mie theory assuming spherical non-absorbing particles with refractive index such as >2.0, or >2.3.

In certain aspects, nanocrystals with a refractive index of at least 2.0, more preferably at least 2.1 may be used to increase the refractive index of the polymer matrix. Such nanocrystals may have a lower refractive index than the scattering particles. For example, nanocrystals may include one or more metal oxides. The particle size of the nanocrystals may be less than 30 nm in some aspects, or in particular aspects less than 20 nm so that they do not contribute to light scattering. These smaller non-scattering particles are not included in the description of the particle size distribution of scattering particles.

The refractive index of the polymer forming the polymer matrix may be between about 1.2 and about 1.6, more preferably at least 1.5. The polymer may include, but is not limited to, silicone, epoxy resin, unsaturated polymer, poly(meth)acrylate, polyimide, polyurethane, polysulfone, polyethersulfone, inorganic sol-gel, and combinations thereof.

The polymer matrix may include nanocrystals and may exhibit a refractive index of 1.7 in some aspects, or at least 1.8 in particular aspects. The nanocrystals may have negligible absorption (e.g., less than 5%, preferably less than 1%) at wavelengths greater than 460 nm.

Incorporation of nanocrystals into the polymer matrix should not decrease the transparency below 80% (400-800 nm). Additionally or alternatively, negligible absorption may be defined as an extinction coefficient (k) values less than 10⁻³. Therefore, high refractive index polymers without significant parasitic absorption characteristics are particularly suitable as the “polymer matrix” or host medium in the present disclosure.

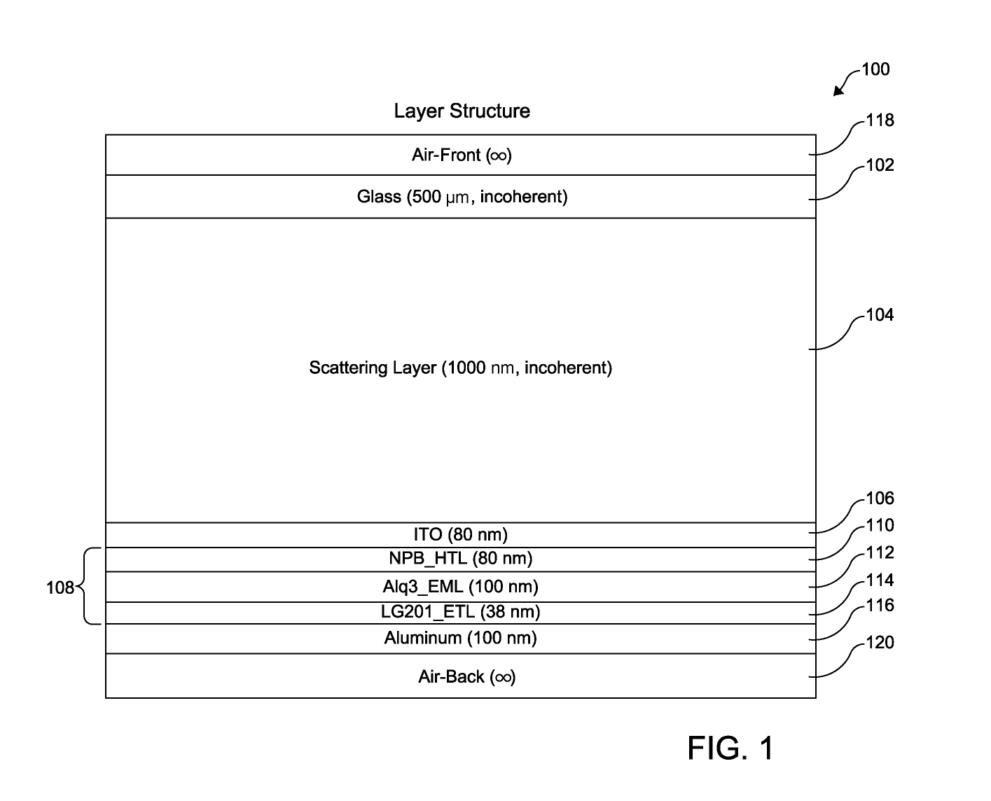

FIG. 1 illustrates a schematic of an OLED device 100 including a substrate 102, a scattering layer 104, an anode 106, a luminescent region 108 (also referred to as an OLED), and a cathode 116.

The OLED device 100 includes one or more of the substrates 102 or supporting members. The substrates 102 may be flexible. Suitable materials for the substrates 102 may include, but are not limited to, glass or polymers that may include polycarbonate, polyethylene terephthalate, polybutylene terephthalate, polyethersulfone, polyimide, polyethylene naphthalate, poly(meth)acrylate, polycyclic olefin, polyurethane, epoxy polymer, poly(methyl methacrylate), and combinations thereof. As shown in FIG. 1, the substrate 102 is a glass substrate (e.g., refractive index: 1.5, thickness: 500 micrometer (μm)). As described herein, other refractive indexes and thicknesses may be used.

The scattering layer 104 may include a polymer matrix and a light scattering component disposed in the polymer matrix. The polymer matrix may include, but is not limited to, silicone, epoxy resin, unsaturated polymer, poly(meth)acrylate, polyimide, polyurethane, polysulfone, polyethersulfone and combinations thereof. The light scattering component may include nanoparticles of polydisperse particle size distribution. Each of at least 60% of the nanoparticles has a particle size of less than 100 nm, and each of 80-100% of the nanoparticles has a particle size of less than 200 nm. The nanoparticles further include a surface modifier that may include, but is not limited to silanes, siloxanes, phosphonic acids, boronic acid, carboxylic acids, oleic acid, or amines and combinations thereof.

The scattering layer 104 may include a polymer matrix, a first portion of light scattering particles dispersed in the polymer matrix. An average particle size of the first portion of light scattering particles is less than 100 nm. A second portion of light scattering particles is dispersed in the polymer matrix. An average particle size of the second portion of light scattering particles is less than 200 nm. The first portion of light scattering nanoparticles may include at least 60% of the total number of light scattering particles and the second portion of light scattering particles may include 20-40% of the total number of light scattering particles, excluding the first portion.

The anode 106 may be formed from indium tin oxide (e.g., refractive index (n)=1.88 & extinction coefficient (k)=0 at 570 nm, thickness: 80 nm) or other materials such as silver. As such, the luminescent region 108 may provide a narrow emission spectrum band due at least in part to the micro cavity effect between the reflective cathode 116 (e.g., aluminum cathode (n=0.84 & k=5.82 at 570 nm, thickness: 100 nm) and the anode 106.

The luminescent region 108 may include a hole transport layer (HTL) 110, an emitting material layer (EML) 112, and an electron transport layer (ETL) 114 arranged in a stacked configuration. The HTL 110 may be configured to transfer the injected holes to the emitting layer. The ETL 114 facilitates the injection and transfer of electrons from the cathode 116. The EML 112 may be configured to combine the holes and electrons and to convert to light energy (e.g., emitted light). The emissive theory of the organic light-emitting diodes is based on injections of electrons and holes, which come from the anode 106 and cathode 116. After recombining within the EML 112, the energy is transferred into visible light. As an example, OLED stack includes N,N′-bis(naphthalen-1-yl)-N,N′-bis(phenyl)-benzidine (NPB) as the HTL 110 (e.g., refractive index: n=1.78 & k=0.005 at 570 nm, thickness: 80 nm), tris(8-hydroxyquinolinato)aluminum (Alq3) as the EML 112 (e.g., refractive index: n=1.73 & k=0 at 570 nm, thickness: 100 nm), 2-(4-(9,10-Di(naphthalen-2-yl)anthracen-2-yl)phenyl)-1-phenyl-1H-benzo[d]imidazole (LG201) as the ETL 114 (e.g., refractive index: n=1.60 & k=0.05 at 570 nm, thickness: 38 nm).

The OLED device 100 may include air interfaces 118, 120 (refractive index: 1.0) disposed at opposite ends of the stack.

As will be discussed in further detail, the scattering layer 104 may be or may include ZrO₂ nanocrystals (e.g., 90 wt %, refractive index: n=1.9 & k<10⁻³, average particle size: 5 nm, monodisperse particle distribution) and TiO₂ scattering particles (according to Table 1). Scattering particles with a higher refractive index are preferred since sufficient light scattering can be achieved at lower loadings. The example scattering layer 104 preferably has a thickness of 0.5-4 μm in some aspects, or in particular aspects 1 μm. The amount of scattering particles may depend on the thickness of the layer. For thicker layers (above 1 μm) lower loadings of the scattering particles may be used.

TABLE 1
Light extraction gain comparisons

| | Refractive index of the | Particle distribution type & | Loading | Extraction |
|---|---|---|---|---|
| | scatterer | Size | (vol %) | Gain (%) |
| C. Ex. 1 | 2.24 (smaller size TiO₂) | Monodisperse (std < 5%, | 20 | 63 |
| | | narrow distribution), d = 60 nm | | |
| C. Ex. 2 | 2.24 (smaller size TiO₂) | Monodisperse (std < 5%, | 50 | 88 |
| | | narrow distribution), d = 60 nm | | |
| C. Ex. 3 | 2.24 (smaller size TiO₂) | Polydisperse, 89% of the | 47 | 60 |
| | | particles with d < 40 nm, 11% | | |
| | | of the particles with 40 nm < | | |
| | | d < 60 nm | | |
| C. Ex. 4 | 2.24 (smaller size TiO₂) | Polydisperse, 89% of the | 47 | 98 |
| | | particles with d < 80 nm, 11% | | |
| | | of the particles with 80 nm < | | |
| | | d < 120 nm | | |
| C. Ex. 5 | 2.24 (smaller size TiO₂) | Gaussian (std: 3 nm), d = 40 nm | 50 | 57 |
| C. Ex. 6 | 2.39 (TiO₂) | Gaussian (std: 3 nm), d = 40 nm | 50 | 77 |
| C. Ex. 7 | 2.39 (TiO₂) | Polydisperse, 89% of the | 47 | 79 |
| | | particles with d < 40 nm, 11% | | |
| | | of the particles with 40 nm < | | |
| | | d < 60 nm | | |
| C. Ex. 8 | 2.39 (TiO₂) | Monodisperse (std < 5%, | 20 | 83 |
| | | narrow distribution), d = 60 nm | | |
| C. Ex. 9 | 2.39 (TiO₂) | Monodisperse (std < 5%, | 30 | 93 |
| | | narrow distribution), d = 100 nm | | |
| Ex. 1 | 2.39 (TiO₂) | Polydisperse with 67% of the | 15 | 105 |
| | | particles d <100 nm, 33% the | | |
| | | particles 100 nm < d < 200 nm | | |
| Ex. 2 | 2.39 (TiO₂) | Polydisperse with 60% of the | 15 | 106 |
| | | particles d <100 nm, 40% the | | |
| | | particles 100 nm < d < 200 nm | | |
| Ex. 3 | 2.39 (TiO₂) | Polydisperse with 80% of the | 15 | 104 |
| | | particles d <100 nm, 20% the | | |
| | | particles 100 nm < d < 200 nm | | |

As shown in Table 1 in C.Ex. 1, when the refractive index of the scattering particles was set to 2.24, the light extraction gain for 60 nm diameter (d) particles, in which the particles possess a monodisperse particle size distribution, is 63% at 20 vol % concentration. The extraction gain can be further increased by increasing the loading of scattering particles to 50 vol % while maintaining the refractive index and particle size distribution. In the case of C.Ex.2, the simulated extraction gain is 88%. These results indicate that the scattering is insufficient due to small particle size of the scatterers. As a result, significantly high (costly and non-practical) loadings of light scatterers (or larger layer thicknesses) are needed to achieve sufficient light extraction efficiency (>80%).

Changing the particle size distribution to a polydisperse model in C.Ex.3, in which 89% of the particles have a particle size less than 40 nm and 11% of the particles have a particle size between 40 and 60 nm, gives a similar extraction efficiency gain (60%) as that of C.Ex.1 (63%). The effect of particle size on the light extraction is significant as shown in C.Ex.4. An extraction gain of 98% can be achieved by increasing the particle size of the scatterers to 80 nm<d<120 nm while maintaining the particle size distribution model and refractive index values.

On the other hand, in C.Ex.5 a Gaussian particle size distribution with particles having a particle size of 40 nm (standard deviation of 3 nm) results in an extraction gain of 57% at 50 vol % concentration. As shown in C.Ex.6, particles with the same particle size distribution but possessing a higher refractive index value allow 13% more light (77% extraction gain) to be extracted compared to those in C.Ex.5. Due to the large refractive index contrast between the high refractive index layer and TiO₂ scattering nanoparticles, strong scattering was obtained.

In C.Ex.7, using scattering particles exhibiting a polydisperse particle size distribution, in which 89% of the particles have a size of d<40 nm, and 11% of the particles are 40 nm<d<60 nm, leads to a similar extraction gain as particles with a Gaussian type distribution in C.Ex.6. Additionally, the scattering particle loading required in both C.Ex.6 and C.Ex.7 are similar (˜50 vol %).

However, by using a monodisperse distribution of particles with a main particle size of 60 nm (standard deviation less than 5%), a significant reduction in the scatterer loading can be achieved. As shown in C.Ex.8, only 20 vol % scattering particles present in the polymer matrix is sufficient to give 83% light extraction gain.

In contrast, the light extraction layer in Ex.1 comprising of scattering particles at a concentration of 15 vol % with a positively skewed polydisperse particle size distribution in which 67% of the particles have a particle size of less than 100 nm, and 33% of the particles have a particle size of between 100 and 200 nm, provides an excellent enhancement in extraction efficiency (105% gain). Additionally, changing the ratio of small to big particles to 60:40 or 80:20, respectively in Ex.2 and Ex.3 results in similar light extraction efficiency enhancements.

Therefore, a light scattering polymer matrix composition including nanoparticles (refractive index: 2.39) of a polydisperse particle size distribution—at least 60% of the nanoparticles having a particle size of less than 100 nm and 20-40% of the nanoparticles having a particle size of between 100 and 200 nm—provides excellent optical characteristics for the resulting internal light extraction layer.

On the other hand, a monodisperse particle size distribution of the same scattering particles with a particle size of 100 nm in C.Ex.9 shows significantly less efficiency enhancement (90%) even at higher loading levels (30%). Therefore, using a particle distribution of the scattering particles in the polymer matrix characterized by an optimal ratio of large versus small particles is essential for achieving the largest light extraction efficiency enhancement while being cost effective.

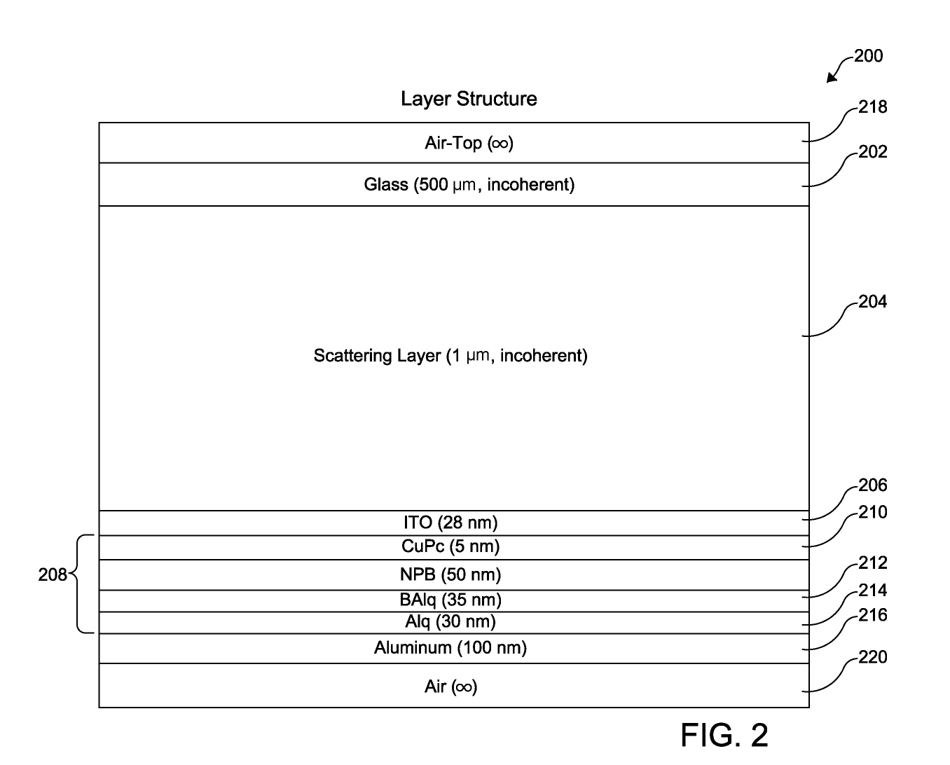

The effectiveness of many internal light extraction layers based on scattering effect is highly wavelength dependent, which makes them incompatible with white light emitting devices. In principle, a scattering layer possessing a weak wavelength dependence over visible wavelengths provides homogenous improvement of light extraction across the emission range of white OLED. In order to test the wavelength dependency of Ex. 1, it has been modelled in a white OLED. For comparison, C.Ex.2 has also been evaluated in the same OLED stack. The layer stack configuration of the white OLED is shown in FIG. 2.

Several layers may include a white light LED. Often, a white light OLED device may include more than ten layers. For purposes of the present disclosure, a white light OLED device may include the layers as present in FIG. 2.

FIG. 2 illustrates a schematic of an OLED device 200 including a substrate 202, a scattering layer 204, an anode 206, a luminescent region 208 (also referred to as an OLED), and a cathode 216.

The OLED device 200 includes one or more of the substrates 202 or supporting members. The substrates 202 may be flexible. Suitable materials for the substrates 202 may include, but are not limited to, glass, or a polymer including polycarbonate, polyethylene terephthalate, polybutylene terephthalate, polyethersulfone, polyimide, polyethylene naphthalate, poly(meth)acrylate, polycyclic olefin, polyurethane, epoxy polymer, poly(methyl methacrylate) and combinations thereof. As shown in FIG. 2, the substrate 202 is a glass substrate (e.g., refractive index: 1.5, thickness: 500 μm). As described herein, other refractive indexes and thicknesses may be used.

The scattering layer 204 may include a polymer matrix and a light scattering component disposed in the polymer matrix. The polymer may include, but is not limited to, silicone, epoxy resin, unsaturated polymer, poly(meth)acrylate, polyimide, polyurethane, polysulfone, polyethersulfone and combinations thereof. The light scattering component may include nanoparticles of polydisperse particle size distribution. Each of at least 60% of the nanoparticles has a particle size of less than 100 nm, and each of 80-100% of the nanoparticles has a particle size of less than 200 nm. The nanoparticles may further include a surface modifier that may include, but is not limited to silanes, siloxanes, phosphonic acids, boronic acids, carboxylic acids, oleic acid, or amines and combinations thereof.

The scattering layer 204 may include a polymer matrix, a first portion of light scattering particles dispersed in the polymer matrix. An average particle size of the first portion of light scattering particles is less than 100 nm. A second portion of light scattering particles is dispersed in the polymer matrix. An average particle size of the second portion of light scattering particles is less than 200 nm. The first portion of light scattering nanoparticles may include at least 60% of the total number of light scattering particles and the second portion of light scattering particles may include 20-40% of the total number of light scattering particles, excluding the first portion. As shown in FIG. 2, the scattering layer 204 may include ZrO₂ nanocrystals (e.g., 90 wt %, refractive index: n=1.9 & k<10⁻³, average particle size: 5 nm, monodisperse particle distribution) and TiO₂ scattering particles (according to Table 1). The thickness of the scattering layer 204 may be 1 μm.

The anode 206 may include indium tin oxide (e.g., n=1.88 & k=0 at 570 nm, thickness: 80 nm), fluorine doped tin oxide, aluminum doped zinc oxide or other materials such as, for example, carbon nanotubes, silver or copper nanowires, or metal oxide/silver/metal oxide electrodes. As such, the luminescent region 208 may provide a narrow emission spectrum band due at least in part to the micro cavity effect between the reflective cathode 216 (e.g., aluminum cathode (n=0.84 & k=5.82 at 570 nm, thickness: 100 nm)) and the anode 206.

The luminescent region 208 may include a hole transport layer (HTL) 210, an emitting material layer (EML) 212, and an electron transport layer (ETL) 214 arranged in a stacked configuration. The HTL 210 may be configured to transfer the injected holes to the emitting layer. The ETL 214 facilitates the injection and transfer of electrons from the cathode 216. The EML 212 may be configured to combine the holes and electrons and to convert to light energy (e.g., emitted light). The emissive theory of the organic light-emitting diodes is based on injections of electrons and holes, which come from the anode 206 and cathode 216. After recombining within the EML 212, the energy is transferred into visible light.

The HTL layer may include, but is not limited to, N,N′-bis(naphthalen-1-yl)-N,N′-bis(phenyl)-benzidine (α-NPD), 4,4′,4″-tris(N-3-methylphenyl-N-phenylamino)triphenylamine (m-MTDATA), N,N′-bis(naphthalen-1-yl)-N,N′-bis(phenyl)-benzidine (NPB) and a combination of poly(3,4-ethylene dioxythiophene) and poly(styrene sulfonic acid) (PEDOT:PSS). The ETL layer may include, for example but not limited to, 2,5-bis(5-tert-butyl-2-benzoxazolyl)thiophen (BBOT), 4,7-diphenyl-1,10-phenanthroline (BPhen), (3,5-bis(5-(4-tert-butylphenyl)-1,3,4-oxadiazol-2-yl)-benzene) (OXA), 1,3-bis[2-(4-tert-butylphenyl)-1,3,4-oxadiazo-5-yl]benzene (OXA-7), 2-(4-biphenylyl)-5-(4-tert-butylphenyl) 1,3,4-oxadiazole (PBD), 2,2′,2″-(1,3,5-benzinetriyl)-tris(1-phenyl-1-H-benzimidazole) (TPBi), and combinations thereof. Exemplary EML materials are well known in the art and may be characterized by: the emitting polymer, the fluorescent dopant in the polymer, or a phosphorescent emitter in the polymer, as well as by the thermally evaporated small molecule based material (which may be fluorescent, phosphorescent, or a combination thereof). As a specific example, OLED stack includes CuPc as the HTL 210 (refractive index: n=1.44 & k=0.54 at 570 nm, thickness: 5 nm), BAlq as the EML 212, (refractive index: n=1.70 & k=0 at 570 nm, thickness: 35 nm), Alq as the ETL 214, (refractive index: n=1.71 & k=0.024 at 570 nm, thickness: 30 nm).

The OLED device 200 may include air interfaces 218, 220 (refractive index: 1.0) disposed at opposite ends of the stack.

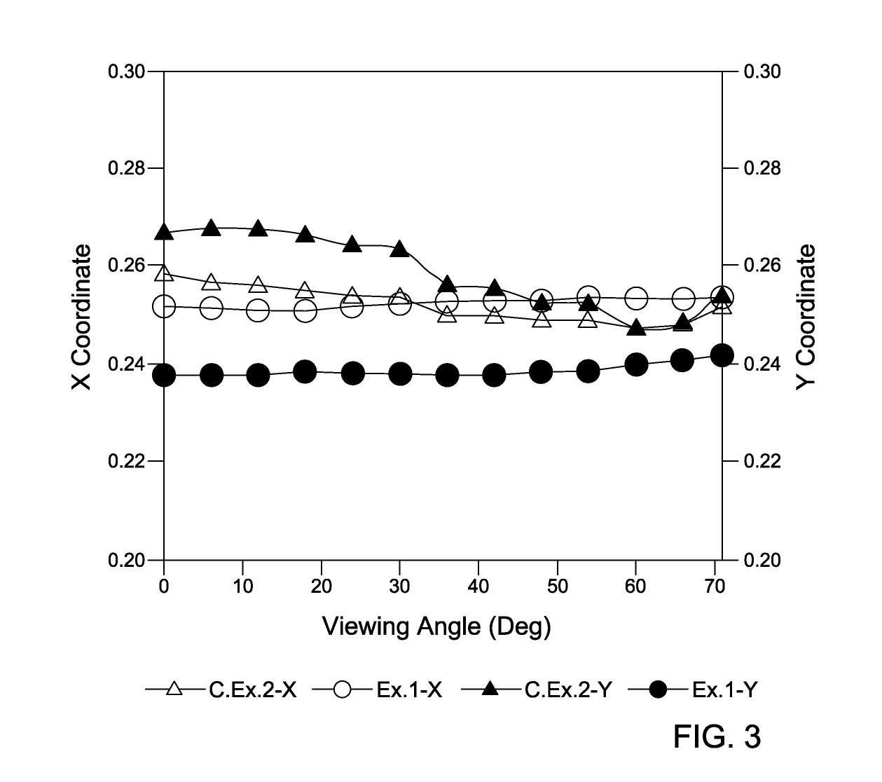

As depicted in FIG. 3, while the color (CIE x, y coordinates) of the light emitted in the presence of C.Ex.2 as internal light extraction layer change strongly with the viewing angle, the emission in the presence of Ex. 1 is extremely stable over all angles. Strong changes in perceived color with viewing angle are common for many white OLEDs. The maximum change in the Commission Internationale de l'Eclairage (CIE) coordinates over the 70 degree forward viewing cone is Δ (x, y) are (0.002, 0.003) with Ex.1, and (0.007, 0.013) with C.Ex.3. The change in the xy coordinates with Ex. 1 is considerably small and any change in hue cannot be noticed by human eye when the white OLED is tilted. As such. Ex. 1 provides an enhanced internal light extraction layer.

### Definitions

It is to be understood that the terminology used herein is for the purpose of describing particular aspects only and is not intended to be limiting. As used in the specification and in the claims, the term “comprising” can include the embodiments “consisting of” and “consisting essentially of.” Unless defined otherwise, all technical and scientific terms used herein have the same meaning as commonly understood by one of ordinary skill in the art to which this disclosure belongs. In this specification and in the claims, which follow, reference will be made to a number of terms, which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one value (first value) to another value (second value). When such a range is expressed, the range includes in some aspects one or both of the first value and the second value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the designated value, approximately the designated value, or about the same as the designated value. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

As used herein, the term “light” means electromagnetic radiation including ultraviolet, visible or infrared radiation. Whereas the focus for most OLEDs is on visible (400-700 nm) light.

As used herein, the term “transparent” means that the level of transmittance for a disclosed composition is greater than 50%. In some aspects, the transmittance can be at least 60%, 70%, 80%, 85%, 90%, or 95%, or any range of transmittance values derived from the above exemplified values. In the definition of “transparent”, the term “transmittance” refers to the amount of incident light that passes through a sample measured in accordance any number of known standards, such as, for example, ASTM D1003.

As used herein, the term “layer” includes sheets, foils, films, laminations, coatings, blends of organic polymers, metal plating, and adhesion layer(s), for example. Further, a “layer” as used herein need not be planar, but may alternatively be folded, bent or otherwise contoured in at least one direction, for example.

Unless otherwise stated to the contrary herein, all test standards are the most recent standard in effect at the time of filing this application.

### Aspects

The present disclosure comprises at least the following aspects.

Aspect 1A. A composition comprising: a polymer matrix; and a light scattering component disposed in the polymer matrix, the light scattering component comprising nanoparticles of polydisperse particle size distribution, wherein each of at least 60% of the nanoparticles has a particle size of less than 100 nm, preferably 30 to 100 nm, and wherein each of 80-100% of the nanoparticles has a particle size of less than 200 nm.

Aspect 1B. A composition consisting of: a polymer matrix; and a light scattering component disposed in the polymer matrix, the light scattering component comprising nanoparticles of polydisperse particle size distribution, wherein each of at least 60% of the nanoparticles has a particle size of less than 100 nm, preferably 30 to 100 nm, and wherein each of 80-100% of the nanoparticles has a particle size of less than 200 nm.

Aspect 1C. A composition consisting essentially of: a polymer matrix; and a light scattering component disposed in the polymer matrix, the light scattering component comprising nanoparticles of polydisperse particle size distribution, wherein each of at least 60% of the nanoparticles has a particle size of less than 100 nm, preferably 30 to 100 nm, and wherein each of 80-100% of the nanoparticles has a particle size of less than 200 nm.

Aspect 2. The composition of any one of aspects 1A-1C, wherein the nanoparticles have an average refractive index of greater than 2.0.

Aspect 3. The composition of any one of aspects 1A-1C, wherein the nanoparticles have an average refractive index of greater than 2.3.

Aspect 4. The composition of any one of aspects 1A-3, wherein the nanoparticles comprise at least one type of inorganic metal oxide particle.

Aspect 5. The composition of any one of aspects 1A-3, wherein the nanoparticles comprise TiO₂, ZrO₂, PbS, ZnS, SiO₂, ZnO or a combination thereof.

Aspect 6. The composition of any one of aspects 1A-5, further comprising one or more nanocrystals disposed in the polymer matrix.

Aspect 7. The composition of aspect 6, wherein the nanocrystals are non-scattering.

Aspect 8. The composition of aspect 6, wherein the one or more nanocrystals comprises surface modified and/or un-modified inorganic metal oxide particles.

Aspect 9. The composition of any one of aspects 6-8, wherein the one or more nanocrystals have a particle size of less than 30 nm.

Aspect 10. The composition of any one of aspects 6-9, wherein the one or more nanocrystals have a particle size of less than 20 nm.

Aspect 11. The composition of any one of aspects 6-10, wherein the one or more nanocrystals have a refractive index of greater than 2.

Aspect 12. The composition of any one of aspects 6-10, wherein the one or more nanocrystals have a refractive index of greater than 2.1.

Aspect 13. The composition of any one of aspects 6-12, wherein the refractive index of the one or more nanocrystals is less than an average refractive index of the nanoparticles.

Aspect 14. The composition of any one of aspects 6-13, wherein the nanocrystals comprise TiO₂, ZrO₂, PbS, ZnS, SiO₂, ZnO, or a combination thereof.

Aspect 15. The composition of any one of aspects 1A-14, wherein the polymer matrix has a refractive index of from about 1.1 to about 2.3.

Aspect 16. The composition of any one of aspects 1A-14, wherein the polymer matrix has a refractive index of from about 1.1 to about 1.8.

Aspect 17. The composition of any one of aspects 1A-14, wherein the polymer matrix has a refractive index of from about 1.2 to about 1.6.

Aspect 18. The composition of any one of aspects 1A-17, wherein the nanoparticles further comprise a surface modifier.

Aspect 19. The composition of aspect 18, wherein the surface modifier comprises silanes, siloxanes, phosphonic acids, boronic acids, carboxylic acids, oleic acids, or amines, or a combination thereof.

Aspect 20. A light extraction layer for a layered organic light-emitting diode (OLED) device comprising the composition of any one of aspects 1A-19.

Aspect 21. A method of forming a light extraction layer for a layered organic light-emitting diode (OLED) device, the method comprising disposing the composition of any one of aspects 1A-19 adjacent a substrate.

Aspect 22A. A composition comprising: a polymer matrix; and a first portion of light scattering particles dispersed in the polymer matrix, wherein an average particle size of the first portion of light scattering particles is less than 100 nm, preferably 30 to 100 nm; and a second portion of light scattering particles dispersed in the polymer matrix, wherein an average particle size of the second portion of light scattering particles is less than 200 nm, wherein the first portion of light scattering nanoparticles comprises at least 60% of the total number of light scattering particles and the second portion of light scattering particles comprises 20-40% of the total number of light scattering particles, excluding the first portion.

Aspect 22B. A composition consisting of: a polymer matrix; and a first portion of light scattering particles dispersed in the polymer matrix, wherein an average particle size of the first portion of light scattering particles is less than 100 nm, preferably 30 to 100 nm; and a second portion of light scattering particles dispersed in the polymer matrix, wherein an average particle size of the second portion of light scattering particles is less than 200 nm, wherein the first portion of light scattering nanoparticles comprises at least 60% of the total number of light scattering particles and the second portion of light scattering particles comprises 20-40% of the total number of light scattering particles, excluding the first portion.

Aspect 22C. A composition consisting essentially of: a polymer matrix; and a first portion of light scattering particles dispersed in the polymer matrix, wherein an average particle size of the first portion of light scattering particles is less than 100 nm, preferably 30 to 100 nm; and a second portion of light scattering particles dispersed in the polymer matrix, wherein an average particle size of the second portion of light scattering particles is less than 200 nm, wherein the first portion of light scattering nanoparticles comprises at least 60% of the total number of light scattering particles and the second portion of light scattering particles comprises 20-40% of the total number of light scattering particles, excluding the first portion.

Aspect 23. The composition of any one of aspects 22A-22C, wherein the light scattering particles have an average refractive index of greater than 2.0.

Aspect 24. The composition of any one of aspects 22A-22C, wherein the light scattering particles have an average refractive index of greater than 2.3.

Aspect 25. The composition of any one of aspects 22A-24, wherein the light scattering particles comprise at least one type of inorganic metal oxide particle.

Aspect 26. The composition of any one of aspects 22A-24, wherein the light scattering particles comprise TiO₂, ZrO₂, PbS, ZnS, SiO2, ZnO, or a combination thereof.

Aspect 27. The composition of any one of aspects 22A-26, further comprising one or more nanocrystals disposed in the polymer matrix.

Aspect 28. The composition of aspect 26, wherein the one or more nanocrystals comprises surface modified and/or un-modified inorganic metal oxide particles.

Aspect 29. The composition of any one of aspects 27-28, wherein the one or more nanocrystals have a particle size of less than 30 nm.

Aspect 30. The composition of any one of aspects 27-28, wherein the one or more nanocrystals have a particle size of less than 20 nm.

Aspect 31. The composition of any one of aspects 27-28, wherein the one or more nanocrystals have a refractive index of greater than 2.

Aspect 32. The composition of any one of aspects 27-28, wherein the one or more nanocrystals have a refractive index of greater than 2.1.

Aspect 33. The composition of any one of aspects 27-32, wherein the refractive index of the one or more nanocrystals is less than an average refractive index of the nanoparticles.

Aspect 34. The composition of any one of aspects 27-33, wherein the polymer matrix has a refractive index of from about 1.1 to about 2.3.

Aspect 35. The composition of any one of aspects 27-33, wherein the polymer matrix has a refractive index of from about 1.1 to about 1.8.

Aspect 36. The composition of any one of aspects 27-33, wherein the polymer matrix has a refractive index of from about 1.2 to about 1.6.

Aspect 37. The composition of any one of aspects 22A-36, wherein the nanoparticles further comprise a surface modifier.

Aspect 38. The composition of aspect 37, wherein the surface modifier comprises silanes, siloxanes, phosphonic acids, boronic acid, carboxylic acids, oleic acid, or amines, or a combination thereof.

Aspect 39. A light extraction layer for a layered organic light-emitting diode (OLED) device comprising the composition of any one of aspects 22A-38.

Aspect 40. A method of forming a light extraction layer for a layered organic light-emitting diode (OLED) device, the method comprising disposing the composition of any one of aspects 22A-40 adjacent a substrate.

1. A composition comprising:
a polymer matrix; and
a light scattering component disposed in the polymer matrix, the light scattering component comprising nanoparticles of polydisperse particle size distribution, wherein at least 60% of the nanoparticles have a particle size of less than 100 nm and from 20-40% of the nanoparticles have a particle size of from 100 nm to 200 nm.

2. The composition of claim 1, wherein the nanoparticles have an average refractive index of greater than 2.0.

3. The composition of claim 1, wherein the nanoparticles have an average refractive index of greater than 2.3.

4. The composition of claim 1, wherein the nanoparticles comprise at least one type of inorganic metal oxide particle.

5. The composition of claim 1, wherein the nanoparticles comprise TiO₂, ZrO₂, PbS, ZnS, SiO₂, ZnO, or a combination thereof.

6. The composition of claim 1, further comprising one or more non-scattering nanocrystals disposed in the polymer matrix.

7. The composition of claim 6, wherein the one or more non-scattering nanocrystals comprises surface modified and/or un-modified inorganic metal oxide particles.

8. The composition of claim 6, wherein the one or more non-scattering nanocrystals have a particle size of less than 30 nm.

9. The composition of claim 6, wherein the one or more non-scattering nanocrystals have a particle size of less than 20 nm.

10. The composition of claim 6, wherein the one or more non-scattering nanocrystals have a refractive index of greater than 2.

11. The composition of claim 6, wherein the one or more non-scattering nanocrystals have a refractive index of greater than 2.1.

12. The composition of claim 6, wherein a refractive index of the one or more non-scattering nanocrystals is less than an average refractive index of the nanoparticles.

13. The composition of claim 6, wherein the non-scattering nanocrystals comprise TiO₂, ZrO₂, PbS, ZnS, SiO₂, ZnO, or a combination thereof.

14. The composition of claim 1, wherein the polymer matrix has a refractive index of from about 1.1 to about 2.3.

15. The composition of claim 1, wherein the polymer matrix has a refractive index of from about 1.2 to about 1.6.

16. The composition of claim 1, wherein the nanoparticles further comprise a surface modifier.

17. The composition of claim 16, wherein the surface modifier comprises silanes, siloxanes, phosphonic acids, boronic acids, carboxylic acids, oleic acids, or amines, or a combination thereof.

18. A light extraction layer for a layered organic light-emitting diode (OLED) device comprising the composition of claim 1.

19. A method of forming a light extraction layer for a layered organic light-emitting diode (OLED) device, the method comprising disposing the composition of claim 1 adjacent a substrate.

20. A composition comprising:
a polymer matrix; and
a first portion of light scattering particles dispersed in the polymer matrix, wherein an average particle size of the first portion of light scattering particles is less than 100 nm; and
a second portion of light scattering particles dispersed in the polymer matrix, wherein an average particle size of the second portion of light scattering particles is from 100 nm to 200 nm,
wherein the first portion of light scattering nanoparticles comprises at least 60% of the total number of light scattering particles and the second portion of light scattering particles comprises 20-40% of the total number of light scattering particles, excluding the first portion.
